(19) United States
(12) Patent Application Publication
(10) Pub. No.: US 2023/0085635 A1
(43) Pub. Date: Mar. 23, 2023

(54) RESISTANCE CHANGE DEVICE AND STORAGE DEVICE

(71) Applicant: Kioxia Corporation, Tokyo (JP)

(72) Inventors: Hiroki KAWAI, Inazawa Aichi (JP); Kasumi YASUDA, Yokohama Kanagawa (JP); Hiroki TOKUHIRA, Kawasaki Kanagawa (JP); Kazuhiro KATONO, Yokkaichi Mie (JP); Akifumi GAWASE, Kuwana Mie (JP); Katsuyoshi KOMATSU, Yokkaichi Mie (JP); Tadaomi DAIBOU, Yokkaichi Mie (JP)

(73) Assignee: Kioxia Corporation, Tokyo (JP)

(21) Appl. No.: 17/687,944

(22) Filed: Mar. 7, 2022

(30) Foreign Application Priority Data
Sep. 17, 2021 (JP) 2021-152202

(51) Int. Cl. H01L 45/00; G11C 13/00

(52) U.S. Cl. CPC H01L 45/144; H01L 45/1253; G11C 13/004; G11C 13/0069

(57) ABSTRACT

A resistance change device of an embodiment includes a first electrode, a second electrode, and a layer disposed between the first electrode and the second electrode and containing a resistance change material. In the resistance change device of the embodiment, the resistance change material contains: a first element including Sb and Te; a second element including at least one element selected from the group consisting of Ge and In; a third element including at least one element selected from the group consisting of Si, N, B, C, Al, and Ti; and a fourth element including at least one element selected from the group consisting of Sc, Y, La, Gd, Zr, and Hf.

### CROSS REFERENCE TO RELATED APPLICATIONS

This application is based upon and claims the benefit of priority from Japanese Patent Application No. 2021-152202, filed on Sep. 17, 2021; the entire contents of which are incorporated herein by reference.

### FIELD

Embodiments disclosed herein relate generally to a resistance change device and a storage device.

### BACKGROUND

A resistance change device having a resistance change layer as a nonvolatile memory layer is used for a storage device. A phase change memory (PCM) with a layer containing a phase change material such as, for example, GeSbTe as the resistance change layer is known as the resistance change device.

### BRIEF DESCRIPTION OF THE DRAWINGS

FIG. 1 is a cross-sectional diagram illustrating a resistance change device according to an embodiment.

FIG. 2 is a perspective diagram illustrating the resistance change device according to the embodiment.

FIG. 3 is a diagram illustrating current-voltage characteristics of a resistance change layer of the resistance change device in a phase change state.

FIG. 4 is a diagram illustrating relative stability (ΔE_{a-c}) of a crystal phase/amorphous phase and cohesive energy of a crystal (E_{coh}(cry)) of a phase change material.

FIG. 5 is a diagram illustrating a change in ΔE_{a-c} and a change in E_{coh}(cry) due to additive elements when various elements are added to a base material of the phase change material.

FIG. 6 is a diagram illustrating a standard deviation of an X—Te bond in an octahedron formed by additive elements X and Te based on the additive element X.

FIG. 7 is a cross-sectional diagram illustrating a first example of a memory cell using the resistance change device according to the embodiment.

FIG. 8 is a cross-sectional diagram illustrating a second example of the memory cell using the resistance change device according to the embodiment.

FIG. 9 is a block diagram illustrating a configuration example of a storage device of the embodiment.

### DETAILED DESCRIPTION

A resistance change device of an embodiment includes a first electrode, a second electrode, and a layer disposed between the first electrode and the second electrode and containing a resistance change material. In the resistance change device of the embodiment, the resistance change material contains: a first element including antimony and tellurium; a second element including at least one element selected from the group consisting of germanium and indium; a third element including at least one element selected from the group consisting of silicon, nitrogen, boron, carbon, aluminum, and titanium; and a fourth element including at least one element selected from the group consisting of scandium, yttrium, lanthanum, gadolinium, zirconium, and hafnium.

The resistance change device and a storage device of the embodiment will be described below with reference to the drawings. In each embodiment, substantially the same components are denoted by the same codes, and explanation thereof is sometimes partially omitted. The drawings are schematic, and a relationship between a thickness and a planar size, thickness proportions of the respective portions, and the like are sometimes different from actual ones. Unless otherwise specified, terms indicating directions such as up and down in the explanation refer to relative directions with a formation surface of a resistance change material layer of a first electrode described below as the top and may differ from an actual direction based on a gravitational acceleration direction.

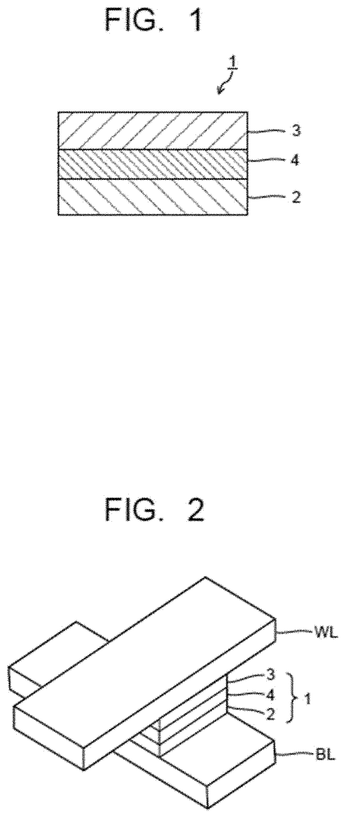

FIG. 1 is a cross-sectional diagram illustrating a basic constitution of a resistance change device 1 of the embodiment, and FIG. 2 is a perspective diagram illustrating the basic constitution of the resistance change device 1 of the embodiment. The resistance change device 1 illustrated in FIG. 1 includes a first electrode 2, a second electrode 3, and a resistance change layer 4 that is disposed between the first electrode 2 and the second electrodes 3, functions as a nonvolatile memory layer, and contains a phase change material as the resistance change material. The resistance change device 1 is disposed at an intersection of a bit line BL and a word line WL to function as a memory cell, as illustrated in FIG. 2. FIG. 2 only illustrates the intersection of one bit line BL and one word line WL, but in reality, a storage device is constituted by disposing the resistance change device 1 as the memory cell at each intersection of many bit lines BL and word lines WL.

The phase change material constituting the resistance change layer 4 contains the first element including antimony (Sb) and tellurium (Te), the second element including at least one element selected from the group consisting of germanium (Ge) and indium (In), the third element including at least one element selected from the group consisting of silicon (Si), nitrogen (N), boron (B), carbon (C), aluminum (Al), and titanium (Ti), and the fourth element including at least one element selected from the group consisting of scandium (Sc), yttrium (Y), lanthanum (La), gadolinium (Gd), zirconium (Zr), and hafnium (Hf).

The phase change material described above contains a base material that contains the first element and the second element. Concrete examples of the base material of the phase change material include Ge—Sb—Te, In—Sb—Te, and Ge—In—Sb—Te. The base material of the phase change material contains compounds such as, for example, Ge₂Sb₂Te₅, Ge₁Sb₂Te₄, In₃Sb₁Te₂, In₃Sb₂Te₁, Sb₂Te₃, GeTe, and In₂Te₃. In addition, the base material of the phase change material preferably contains at least one compound selected from Ge₂Sb₂Te₅, Ge₁Sb₂Te₄, and In₃Sb₁Te₂. By containing such a compound, phase change properties between a crystal phase and an amorphous phase can be obtained reproducibly, and reset and set currents during the phase change can be reduced.

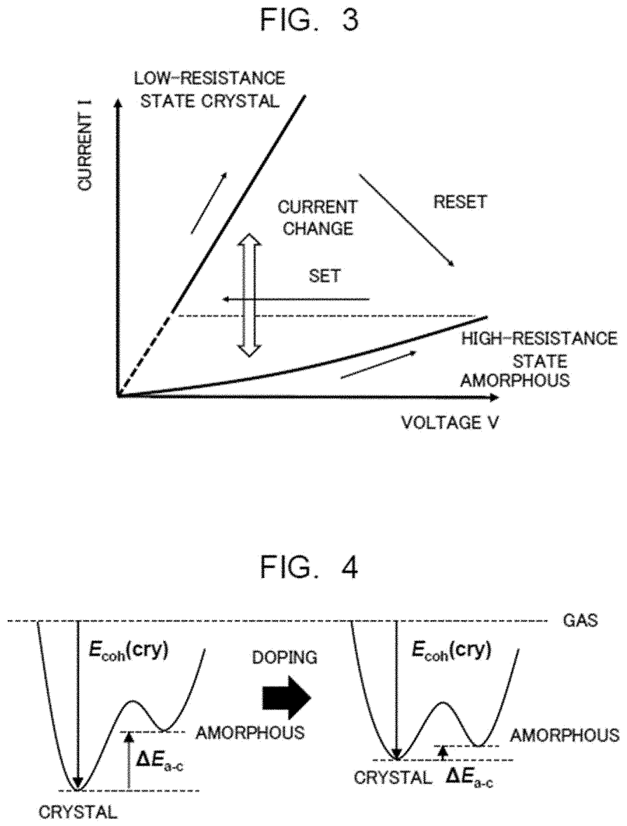

The phase change material has the phase change properties capable of reversibly changing between the amorphous phase and the crystal phase. The phase change material in the crystal phase has low resistance, while the phase change material in the amorphous phase has high resistance. As illustrated in FIG. 3, when the phase change material layer disposed between a pair of electrodes is in a crystalline state, a resistance value thereof is low, resulting in a low-resistance state. On the other hand, when the phase change material layer is in an amorphous state, the resistance value thereof is high, resulting in a high-resistance state. The phase change between the crystalline state and the amorphous state is caused by Joule heating using electrical pulses, for example. As illustrated in FIG. 3, at least a part of the phase change material layer can be made into the amorphous state by heating the phase change material layer in the crystalline state by applying a reset current and then rapidly cooling the layer by rapidly decreasing the reset current. Conversely, the phase change material layer can be made into the crystalline state by heating the phase change material layer in the amorphous state by applying a set current, and then slowly cooling the layer by gradually decreasing the set current. In the resistance change device 1 including a resistance change layer (phase change layer) 4 containing the phase change material, it is desired to decrease the reset current.

In order to decrease the reset current of the resistance change device 1, for example, it is effective to increase electric resistivity of the phase change material when it is in the crystalline state. By increasing the electric resistivity of the phase change material in the crystal phase, the Joule heat at low current increases, which allows the crystal phase to be phase-changed to the amorphous phase at the low current. In this regard, the electric resistivity of the crystal phase can be increased by reducing a crystal grain size. Furthermore, examples of methods to reduce the crystal grain size of the phase change material include (1) lowering a crystal growth rate and (2) promoting crystal nucleation. In the phase change material of the embodiment, elements that contribute to (1) lowering the crystal growth rate and (2) promoting the crystal nucleation, that is, the third and fourth elements, are added to the base material of the phase change material.

FIG. 4 illustrates relative stability (ΔE_{a-c}) of the crystal phase/amorphous phase of the phase change material and cohesive energy of a crystal (E_{coh}(cry)). As illustrated in FIG. 4, driving force for stabilization due to crystallization becomes smaller if ΔE_{a-c} decreases by adding (doping) an additive element to the base material of the phase change material, and therefore crystallization is suppressed, that is, the crystal growth rate is expected to be reduced. The cohesive energy of the crystal (an absolute value of E_{coh}(cry)) increases by adding (doping) the additive element to the base material of the phase change material, which means that the element is a stable dopant in the crystal, and thus crystal nucleation can be expected to be promoted. By satisfying these requirements, the crystal grain size of the phase change material can be reduced, thereby increasing the electric resistivity of the phase change material in the crystal phase and lowering the reset current of the resistance change device 1.

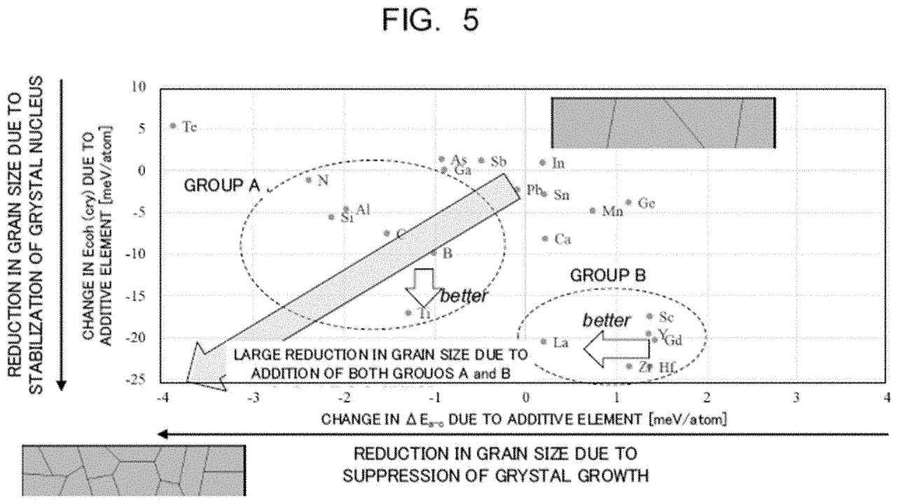

FIG. 5 illustrates a change in ΔE_{a-c} and a change in E_{coh}(cry) due to an additive element when various elements are added to the base material of the phase change material. FIG. 5 illustrates the change in ΔE_{a-c} and the change in E_{coh}(cry) when 0.46 atom % of the additive element is added to Ge₂Sb₂Te₅ as a typical example of the base material of the phase change material. As illustrated in FIG. 5, elements enclosed as group A, that is, Si, N, B, C, Al, and titanium Ti decrease ΔE_{a-c} when added to the base material, which is effective in suppressing the crystal growth. On the other hand, elements enclosed as group B, that is, Sc, Y, La, Gd, Zr, and Hf increase the absolute value of E_{coh}(cry), which is effective in promoting nucleation. Since the elements in these two groups A and B have their specific effects, the crystal grain size of the phase change material can be reduced more effectively by adding at least one element from each of the two groups A and B to the base material of the phase change material. Concretely, an effect of heading toward the lower left of FIG. 5 can be obtained by adding a combination of the elements from the two groups A and B.

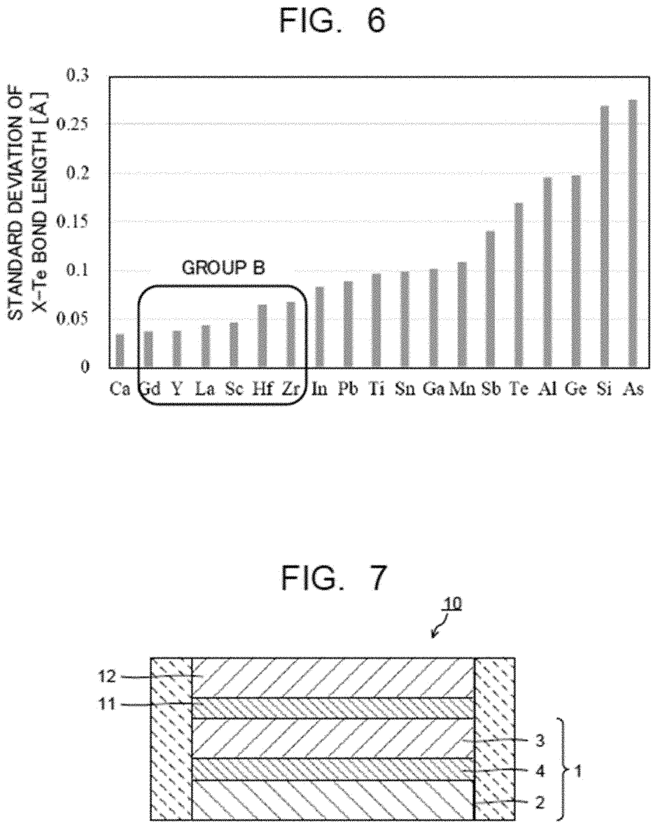

Further, FIG. 6 illustrates a standard deviation of an X—Te bond in an octahedron formed by an element X added to a crystal and surrounding Te. The standard deviation of the X—Te bond is an indicator of a function of the element X as a crystal nucleus. As a value of the standard deviation is smaller, symmetry becomes good and the nucleation is promoted. As illustrated in FIG. 6, the standard deviation of the X—Te bond is smaller in a sequence of Ca, Gd, Y, La, Sc, Hf, and Zr. Among these elements, Ca does not function effectively as the additive element to the base material of the phase change material because E_{coh}(cry) of Ca is small. When elements other than Ca, that is, at least one element selected from Sc, Y, La, Gd, Zr, and Hf is added to the base material of the phase change material, a highly symmetric cubic crystal structure is taken, which is effective in reducing the crystal grain size of the phase change material.

As mentioned above, the effect of heading toward the lower left of FIG. 5 can be obtained by adding the element in group A, that is, the third element including at least one element selected from the group consisting of Si, N, B, C, Al, and Ti, and the element in group B, that is, the fourth element including at least one element selected from the group consisting of Sc, Y, La, Gd, Zr, and Hf, to the base material of the phase change material containing the first and second elements. Therefore, the crystal grain size of the phase change material can be reduced and the electric resistivity of the phase change material in the crystal phase can be increased, resulting in that the reset current of the resistance change device 1 can be lowered.

An addition amount of the third element is preferably 0.1 atom % or more and 16 atom % or less. When the addition amount of the third element exceeds 16 atom %, the phase change properties of the phase change material may not be obtained. When the addition amount of the third element is less than 0.1 atom %, the addition effect of the third element cannot be sufficiently obtained. An addition amount of the fourth element is preferably 0.1 atom % or more and 4 atom % or less. When the addition amount of the fourth element exceeds 4 atom %, the phase change properties of the phase change material may not be obtained. When the addition amount of the fourth element is less than 0.1 atom %, the addition effect of the fourth element cannot be sufficiently obtained.

When the third and fourth elements are added alone, the addition amount of each element cannot be sufficiently increased, so the effect of reducing the crystal grain size of the phase change material cannot be sufficiently increased. For example, when the addition amount of the third element such as N is increased too much, the phase change material such as Ge—Sb—Te cannot be phase-changed. On the other hand, since the fourth element such as Sc has low electronegativity and high positive charge, the addition amount of the fourth element cannot be increased too much because of its strong Coulomb repulsion. In this regard, the addition of the third and fourth elements together can effectively obtain the effect of reducing the crystal grain size of the phase change material while maintaining a moderate addition amount of each element due to the addition effect of each of the third and fourth elements.

The above-mentioned phase change material of the embodiment preferably has a composition represented by:

general expression: (T₁₋ₐMₐ)_{100-x-y}AₓD_{y} (1)

where T is antimony and tellurium, M is at least one element selected from the group consisting of germanium and indium, A is at least one element selected from the group consisting of silicon, nitrogen, boron, carbon, aluminum, and titanium, D is at least one element selected from the group consisting of scandium, yttrium, lanthanum, gadolinium, zirconium, and hafnium, a is a number representing an atomic ratio satisfying 0<a<1, and x and y are numbers representing atom % satisfying 0.1≤x≤16, 0.1≤y≤4, respectively.

The phase change material of the embodiment further preferably has a composition represented by:

general expression: ((Sb₁₋ₐ₁Teₐ₁)₁₋ₐ₂Mₐ₂)_{100-x-y}AₓD_{y} (2)

where M is at least one element selected from the group consisting of germanium and indium, A is at least one element selected from the group consisting of silicon, nitrogen, boron, carbon, aluminum, and titanium, D is at least one element selected from the group consisting of scandium, yttrium, lanthanum, gadolinium, zirconium, and hafnium, a1 and a2 are numbers representing atomic ratios satisfying 0<a1<1 and 0<a2<1, and x and y are numbers representing atom % satisfying 0.1≤x≤16, and 0.1≤y≤4, respectively.

Concrete examples of the phase change material of the embodiment include materials where at least one of the third elements selected from the group consisting of Si, N, B, C, Al, and Ti and at least one of the fourth elements selected from the group consisting of Sc, Y, La, Gd, Zr, and Hf are contained into one compound selected from Ge₂Sb₂Te₅, Ge₁Sb₂Te₄, and In₃Sb₁Te₂. As the third element, Ti is more preferable. As the fourth element, La, which does not promote crystal growth as much as the other elements, is more preferable.

Concrete examples of the phase change material whose base material is Ge₂Sb₂Te₅ include: Ge₂Sb₂Te₅+Si, Sc; Ge₂Sb₂Te₅+Si, Y; Ge₂Sb₂Te₅+Si, La; Ge₂Sb₂Te₅+Si, Gd; Ge₂Sb₂Te₅+Si, Zr; Ge₂Sb₂Te₅+Si, Hf; Ge₂Sb₂Te₅+C, Sc; Ge₂Sb₂Te₅+C, Y; Ge₂Sb₂Te₅+C, La; Ge₂Sb₂Te₅+C, Gd; Ge₂Sb₂Te₅+C, Zr; Ge₂Sb₂Te₅+C, Hf; Ge₂Sb₂Te₅+B, Sc; Ge₂Sb₂Te₅+B, Y; Ge₂Sb₂Te₅+B, La; Ge₂Sb₂Te₅+B, Gd; Ge₂Sb₂Te₅+B, Zr; Ge₂Sb₂Te₅+B, Hf; Ge₂Sb₂Te₅+Al, Sc; Ge₂Sb₂Te₅+Al, Y; Ge₂Sb₂Te₅+Al, La; Ge₂Sb₂Te₅+Al, Gd; Ge₂Sb₂Te₅+Al, Zr; Ge₂Sb₂Te₅+Al, Hf; Ge₂Sb₂Te₅+Ti, Sc; Ge₂Sb₂Te₅+Ti, Y; Ge₂Sb₂Te₅+Ti, La; Ge₂Sb₂Te₅+Ti, Gd; Ge₂Sb₂Te₅+Ti, Zr; Ge₂Sb₂Te₅+Ti, Hf; Ge₂Sb₂Te₅+N, Sc; Ge₂Sb₂Te₅+N, Y; Ge₂Sb₂Te₅+N, La; Ge₂Sb₂Te₅+N, Gd; Ge₂Sb₂Te₅+N, Zr; Ge₂Sb₂Te₅+N, Hf, and the like. Among the above, Ge₂Sb₂Te₅+Ti, La is particularly preferable.

Concrete examples of the phase change material whose base material is Ge₁Sb₂Te₄ include: Ge₁Sb₂Te₄+Si, Sc; Ge₁Sb₂Te₄+Si, Y; Ge₁Sb₂Te₄+Si, La; Ge₁Sb₂Te₄+Si, Gd; Ge₁Sb₂Te₄+Si, Zr; Ge₁Sb₂Te₄+Si, Hf; Ge₁Sb₂Te₄+C, Sc; Ge₁Sb₂Te₄+C, Y; Ge₁Sb₂Te₄+C, La; Ge₁Sb₂Te₄+C, Gd; Ge₁Sb₂Te₄+C, Zr; Ge₁Sb₂Te₄+C, Hf; Ge₁Sb₂Te₄+B, Sc; Ge₁Sb₂Te₄+B, Y; Ge₁Sb₂Te₄+B, La; Ge₁Sb₂Te₄+B, Gd; Ge₁Sb₂Te₄+B, Zr; Ge₁Sb₂Te₄+B, Hf; Ge₁Sb₂Te₄+Al, Sc; Ge₁Sb₂Te₄+Al, Y; Ge₁Sb₂Te₄+Al, La; Ge₁Sb₂Te₄+Al, Gd; Ge₁Sb₂Te₄+Al, Zr; Ge₁Sb₂Te₄+Al, Hf; Ge₁Sb₂Te₄+Ti, Sc; Ge₁Sb₂Te₄+Ti, Y; Ge₁Sb₂Te₄+Ti, La; Ge₁Sb₂Te₄+Ti, Gd; Ge₁Sb₂Te₄+Ti, Zr; Ge₁Sb₂Te₄+Ti, Hf; Ge₁Sb₂Te₄+N, Sc; Ge₁Sb₂Te₄+N, Y; Ge₁Sb₂Te₄+N, La; Ge₁Sb₂Te₄+N, Gd; Ge₁Sb₂Te₄+N, Zr; Ge₁Sb₂Te₄+N, Hf, and the like. Among the above, Ge₁Sb₂Te₄+Ti, La is particularly preferable.

Concrete examples of the phase change material whose base material is In₃Sb₁Te₂ include: In₃Sb₁Te₂+Si, Sc; In₃Sb₁Te₂+Si, Y;In₃Sb₁Te₂+Si, La; In₃Sb₁Te₂+Si, Gd; In₃Sb₁Te₂+Si, Zr; In₃Sb₁Te₂+Si, Hf; In₃Sb₁Te₂+C, Sc; In₃Sb₁Te₂+C, Y; In₃Sb₁Te₂+C, La; In₃Sb₁Te₂+C, Gd; In₃Sb₁Te₂+C, Zr; In₃Sb₁Te₂+C, Hf; In₃Sb₁Te₂+B, Sc; In₃Sb₁Te₂+B, Y; In₃Sb₁Te₂+B, La; In₃Sb₁Te₂+B, Gd; In₃Sb₁Te₂+B, Zr; In₃Sb₁Te₂+B, Hf; In₃Sb₁Te₂+Al, Sc; In₃Sb₁Te₂+Al, Y; In₃Sb₁Te₂+Al, La; In₃Sb₁Te₂+Al, Gd; In₃Sb₁Te₂+Al, Zr; In₃Sb₁Te₂+Al, Hf; In₃Sb₁Te₂+Ti, Sc; In₃Sb₁Te₂+Ti, Y; In₃Sb₁Te₂+Ti, La; In₃Sb₁Te₂+Ti, Gd; In₃Sb₁Te₂+Ti, Zr; In₃Sb₁Te₂+Ti, Hf; In₃Sb₁Te₂+N, Sc; In₃Sb₁Te₂+N, Y; In₃Sb₁Te₂+N, La; In₃Sb₁Te₂+N, Gd; In₃Sb₁Te₂+N, Zr; In₃Sb₁Te₂+N, Hf, and the like. Among the above, In₃Sb₁Te₂+Ti, La is particularly preferable.

As illustrated in FIG. 7, in a memory cell 10 using the resistance change device 1, for example, a switch layer 11 is disposed on the resistance change device 1. The memory cell 10 with the switch layer 11 includes the resistance change device 1 including the resistance change layer 4, the switch layer 11 disposed on the second electrode 3 of the resistance change device 1, and a third electrode 12 disposed on the switch layer 11. The switch layer 11 is disposed to be electrically connected to the resistance change layer 4 and has a function of switching on/off the current to the resistance change layer 4 (switch function).

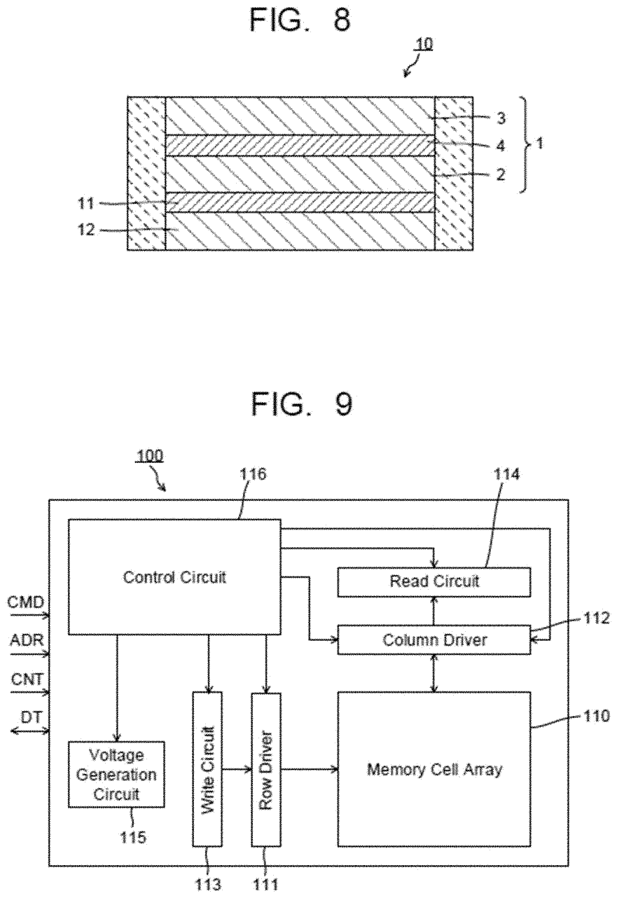

The switch layer 11 has electric properties that rapidly transfer from an off-state with a high resistance value to an on-state with a low resistance value when a voltage of a threshold value (Vth) or more is applied. In other words, when the voltage applied to the switch layer 11 is lower than the threshold value (Vth), the switch layer 11 functions as an insulator and blocks the current flowing through the resistance change layer 4, making the resistance change layer 4 non-selective. When the voltage applied to the switch layer 11 exceeds the threshold value (Vth), the resistance value of the switch layer 11 rapidly decreases and the switch layer 11 functions as a conductor, allowing the current to flow through the switch layer 11 to the resistance change layer 4, making the resistance change layer 4 selective. A structure of the memory cell 10 is not limited to the constitution illustrated in FIG. 7, but the resistance change device 1 may be disposed above the switch layer 11 as illustrated in FIG. 8.

A material that constitutes the switch layer 11 includes, for example, a material containing at least one chalcogen element selected from the group consisting of tellurium (Te), selenium (Se), and sulfur (S). Such a switch material may contain chalcogenide, which is a compound containing the chalcogen element. Materials containing the chalcogen elements may contain at least one element selected from the group consisting of aluminum (Al), gallium (Ga), indium (In), silicon (Si), germanium (Ge), tin (Sn), arsenic (As), phosphorus (P), antimony (Sb), and bismuth (Bi). Furthermore, the materials containing the chalcogen elements may contain at least one element selected from the group consisting of nitrogen (N), oxygen (0), carbon (C), and boron (B). Examples of such a switch material include GeSbTe, GeTe, SbTe, SiTe, AlTeN, GeAsSe, and the like. However, the switch material is not limited to the materials containing the chalcogen elements, but may also be a material that does not contain the chalcogen elements.

In the memory cell 10 with the switch layer 11, the switch layer 11 functions as a heat source when a predetermined voltage is applied to the switch layer 11 to be heated. The heat of the switch layer 11 is applied to the resistance change layer 4 through the second electrode 3 or the first electrode 2, and the phase change material contained in the resistance change layer 4 is heated and melted. In this process, the phase change material of the embodiment is reset at a low current, and the reset current can be reduced. Therefore, it is possible to improve the characteristics of the resistance change device 1 and the memory cell 10.

Next, a storage device of the embodiment will be described with reference to FIG. 9. FIG. 9 is a block diagram illustrating a configuration example of a storage device. A storage device 100 includes a memory cell array 110, a row driver 111, a column driver 112, a write circuit 113, a read circuit 114, a voltage generation circuit 115, and a control circuit 116. The memory cell array 110 includes the memory cells of the embodiment described above.

The row driver 111 controls a plurality of rows of the memory cell array 110. The row driver 111 receives a row address signal from the control circuit 116 based on a decoding result of an address signal ADR input from the outside. The row driver 111 sets a word line WL of the row selected by the row address signal to a selected state. The row driver 111 has circuits such as, for example, a multiplexer (word line selection circuit) and a word line driver.

The column driver 112 controls a plurality of columns of the memory cell array 110. The column driver 112 receives a column address signal from the control circuit 116 based on a decoding result of the address signal ADR. The column driver 112 sets a bit line BL of the column selected by the column address signal to a selected state. The column driver 112 has circuits such as, for example, a multiplexer (bit line selection circuit) and a bit line driver.

The write circuit 113 controls various aspects of data writing operations. The write circuit 113 receives a data signal DT input from the outside. The write circuit 113 supplies write pulses formed by a current and/or voltage to the memory cell array 110 during write operations. This allows data to be written to memory cells MC. The write circuit 113 is electrically connected to the memory cell array 110 through the row driver 111. The write circuit 113 has circuits such as, for example, a voltage source and/or a current source, a pulse generation circuit, and a latch circuit.

The read circuit 114 controls various aspects of data read operations. The read circuit 114 supplies read pulses (for example, read current) to the memory cell array 110 during read operations. The read circuit 114 senses a potential or current value of the bit line BL. Data in the memory cell MC can be read out based on this sense result. The read circuit 114 transfers read out data signal to the outside. The read circuit 114 is connected to the memory cell array 110 through the column driver 112. The read circuit 114 has circuits such as, for example, a voltage source and/or a current source, a pulse generation circuit, a latch circuit, and a sense amplifier circuit.

The write circuit 113 and the read circuit 114 are not limited to circuits that are independent of each other. For example, the write circuit 113 and the read circuit 114 may have common components that are mutually available and may be disposed in the storage device 100 as one integrated circuit.

The voltage generation circuit 115 generates voltages for various operations of the memory cell array 110 using a power supply voltage supplied from the outside. The voltage generation circuit 115 supplies the generated various voltages to the row driver 111, column driver 112, write circuit 113, and read circuit 114.

The control circuit 116 has, for example, a command register and an address register. The control circuit 116 controls the row driver 111, column driver 112, write circuit 113, read circuit 114, and voltage generation circuit 115 based on, for example, a command signal CMD, the address signal ADR, and a control signal CNT input from the outside to perform operations such as the read operation, the write operation, and an erase operation.

The command signal CMD is a signal indicating an operation to be performed by the storage device 100. For example, the address signal ADR is a signal indicating coordinates of one or more memory cells MC to be operated in the memory cell array 110 (hereinafter, referred to as selected cells). The address signal ADR includes the row address signal and the column address signal of the memory cell MC. The control signal CNT is, for example, a signal for controlling an operation timing between the storage device 100 and external devices and an internal operation timing of the storage device 100.

While certain embodiments of the present invention have been described, these embodiments have been presented by way of example only, and are not intended to limit the scope of the inventions. The embodiments described herein may be embodied in a variety of other forms, furthermore, various omissions, substitutions, changes, and so on may be made therein without departing from the spirit of the inventions. The accompanying claims and their equivalents are intended to cover such forms or modifications as would fall within the scope and spirit of the inventions.

What is claimed is:

1. A resistance change device, comprising:
a first electrode; a second electrode; and a layer which is disposed between the first electrode and the second electrode, and contains a resistance change material, wherein
the resistance change material contains: a first element including antimony and tellurium; a second element including at least one element selected from the group consisting of germanium and indium; a third element including at least one element selected from the group consisting of silicon, nitrogen, boron, carbon, aluminum, and titanium; and a fourth element including at least one element selected from the group consisting of scandium, yttrium, lanthanum, gadolinium, zirconium, and hafnium.

2. The device according to claim 1, wherein
the resistance change material contains 0.1 atom % or more and 16 atom % or less of the third element and 0.1 atom % or more and 4 atom % or less of the fourth element.

3. The device according to claim 1, wherein
the resistance change material has a composition represented by:
general expression: (T₁₋ₐMₐ)_{100-x-y}AₓD_{y}
where T is the first element, M is the second element, A is the third element, D is the fourth element, a is a number representing an atomic ratio satisfying 0<a<1, and x and y are numbers representing atom % satisfying 0.1≤x≤16 and 0.1≤y≤4.

4. The device according to claim 1, wherein
the resistance change material has a composition represented by:
general expression: ((Sb₁₋ₐ₁Teₐ₁)₁₋ₐ₂Mₐ₂)_{100-x-y}AₓD_{y}
where M is the second element, A is the third element, D is the fourth element, a1 and a2 are numbers representing atomic ratios satisfying 0<a1<1 and 0<a2<1, and x and y are numbers representing atom % satisfying 0.1≤x≤16 and 0.1≤y≤4.

5. The device according to claim 1, wherein
the resistance change material contains at least one selected from the group consisting of germanium-antimony-tellurium, indium-antimony-tellurium, and germanium-indium-antimony-tellurium.

6. The device according to claim 1, wherein
the resistance change material contains at least one compound selected from the group consisting of Ge₂Sb₂Te₅, Ge₁Sb₂Te₄, In₃Sb₁Te₂, In₃Sb₂Te₁, Sb₂Te₃, GeTe, and In₂Te₃.

7. The device according to claim 1, wherein
the resistance change material contains at least one compound selected from the group consisting of Ge₂Sb₂Te₅, Ge₁Sb₂Te₄, and In₃Sb₁Te₂.

8. The device according to claim 1, further comprising: a switch layer which is electrically connected to the layer containing the resistance change material.

9. A storage device, comprising:
a memory cell array which includes memory cells, and
a control circuit configured to control a read operation and a write operation of the memory cell array,
the memory cells each comprising:
a first electrode; a second electrode; and a layer which is disposed between the first electrode and the second electrode, and contains a resistance change material, wherein
the resistance change material contains: a first element including antimony and tellurium; a second element including at least one element selected from the group consisting of germanium and indium; a third element including at least one element selected from the group consisting of silicon, nitrogen, boron, carbon, aluminum, and titanium; and a fourth element including at least one element selected from the group consisting of scandium, yttrium, lanthanum, gadolinium, zirconium, and hafnium.

10. The device according to claim 9, wherein
the resistance change material contains 0.1 atom % or more and 16 atom % or less of the third element and 0.1 atom % or more and 4 atom % or less of the fourth element.

11. The device according to claim 9, wherein
the resistance change material has a composition represented by:
general expression: (T₁₋ₐMₐ)_{100-x-y}AₓD_{y}
where T is the first element, M is the second element, A is the third element, D is the fourth element, a is a number representing an atomic ratio satisfying 0<a<1, and x and y are numbers representing atom % satisfying 0.1≤x≤16 and 0.1≤y≤4.

12. The device according to claim 9, wherein
the resistance change material has a composition represented by:
general expression: ((Sb₁₋ₐ₁Teₐ₁)₁₋ₐ₂Mₐ₂)_{100-x-y}AₓD_{y}
where M is the second element, A is the third element, D is the fourth element, a1 and a2 are numbers representing atomic ratios satisfying 0<a1<1 and 0<a2<1, and x and y are numbers representing atom % satisfying 0.1≤x≤16 and 0.1≤y≤4.

13. The device according to claim 9, wherein
the resistance change material contains at least one selected from the group consisting of germanium-antimony-tellurium, indium-antimony-tellurium, and germanium-indium-antimony-tellurium.

14. The device according to claim 9, wherein
the resistance change material contains at least one compound selected from the group consisting of Ge₂Sb₂Te₅, Ge₁Sb₂Te₄, In₃Sb₁Te₂, In₃Sb₂Te₁, Sb₂Te₃, GeTe, and In₂Te₃.

15. The device according to claim 9, wherein
the resistance change material contains at least one compound selected from the group consisting of Ge₂Sb₂Te₅, Ge₁Sb₂Te₄, and In₃Sb₁Te₂.

16. The device according to claim 9, wherein
the memory cells each comprise a switch layer which is electrically connected to the layer containing the resistance change material.
